(19) United States
(12) Patent Application Publication
(10) Pub. No.: US 2013/0107137 A1
(43) Pub. Date: May 2, 2013

(54) TELEVISION RECEIVER AND ELECTRONIC DEVICE

(71) Applicants: Junichi NONOMURA, Tokyo (JP); Tetsuo OKAZAKI, Tokyo (JP)

(72) Inventors: Junichi NONOMURA, Tokyo (JP); Tetsuo OKAZAKI, Tokyo (JP)

(73) Assignee: KABUSHIKI KAISHA TOSHIBA, Tokyo (JP)

(21) Appl. No.: 13/584,123

(22) Filed: Aug. 13, 2012

(30) Foreign Application Priority Data
Oct. 28, 2011 (JP) 2011-238027

(51) Int. Cl. H04N 5/64; H05K 5/00

(52) U.S. Cl. 348/836; 361/679.01; 348/E05.128

(57) ABSTRACT

According to one embodiment, an electronic device includes: a housing configured to house a display including a display screen, the housing including an opening; a movable part exposed through the opening and positioned lower than a part of a circumferential portion of the opening, the movable part configured to slide in the opening along an outer surface of the housing; and a stepped portion in a part of a circumferential area of the opening.

### CROSS-REFERENCE TO RELATED APPLICATIONS

This application is based upon and claims the benefit of priority from Japanese Patent Application No. 2011-238027, filed Oct. 28, 2011; the entire contents of which are incorporated herein by reference.

### FIELD

Embodiments described herein relate generally to a television receiver and an electronic device.

### BACKGROUND

Conventionally known are some electronic devices including a movable part provided to the housing thereof and configured to slide along the outer surface of the housing.

In the devices of this type, as an example, it is desirable that unintentional sliding of the movable part be suppressed.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary front view illustrating an example of a television receiver according to a first embodiment;

FIG. 2 is an exemplary side view illustrating the example of the television receiver in the first embodiment;

FIG. 3 is an exemplary perspective view illustrating a part of the example of the television receiver in the first embodiment;

FIG. 4 is an exemplary cross-sectional view viewed along the line IV-IV in FIG. 3 in the embodiment;

FIG. 5 is an exemplary cross-sectional view viewed along the line V-V in FIG. 3 in the embodiment;

FIG. 6 is an exemplary cross-sectional view viewed at the same cross-section as that in FIG. 5, but in a state with the position of an operating part being different from that in FIG. 5 in the embodiment;

FIG. 7 is an exemplary front view illustrating an example of an electronic device according to a second embodiment;

FIG. 8 is an exemplary rear view illustrating the example of the electronic device in the second embodiment;

FIG. 9 is an exemplary side view illustrating the example of the electronic device in the second embodiment;

FIG. 10 is an exemplary side view illustrating the example of the electronic device in the second embodiment, but viewed from a different direction from that in FIG. 9;

FIG. 11 is an exemplary side view illustrating the example of the electronic device in the second embodiment, but viewed from a different direction from those in FIGS. 9 and 10;

FIG. 12 is an exemplary side view illustrating the example of the electronic device in the second embodiment, but viewed from a different direction from those in FIGS. 9 to 11;

FIG. 13 is an exemplary exploded perspective view illustrating the example of the electronic device in the second embodiment;

FIG. 14 is an exemplary plan view illustrating an example of the internal structure of the electronic device in the second embodiment;

FIG. 15 is an exemplary cross-sectional view viewed along the line XV-XV in FIG. 7 in the embodiment;

FIG. 16 is an exemplary perspective view illustrating a part of the example of the electronic device in the second embodiment;

FIG. 17 is an exemplary cross-sectional view viewed along the line XVII-XVII in FIG. 16 in the embodiment;

FIG. 18 is an exemplary perspective view illustrating an example of the electronic device in the second embodiment in a state being supported on a stand;

FIG. 19 is an exemplary plan view of a part of an example of an electronic device according to a first modification;

FIG. 20 is an exemplary cross-sectional view viewed along the line XX-XX in FIG. 19 in the modification;

FIG. 21 is an exemplary plan view of a part of an example of an electronic device according to a second modification;

FIG. 22 is an exemplary plan view of a part of an example of an electronic device according to a third modification;

FIG. 23 is an exemplary cross-sectional view viewed along the line XXIII-XXIII in FIG. 22 in the modification;

FIG. 24 is an exemplary plan view of a part of an example of an electronic device according to a fourth modification;

FIG. 25 is an exemplary plan view of a part of an example of an electronic device according to a fifth modification; and

FIG. 26 is an exemplary plan view of a part of an example of an electronic device according to a sixth modification.

### DETAILED DESCRIPTION

In general, according to one embodiment, a television receiver comprises: a display comprising a display screen; an electronic component electrically connected to the display; a housing configured to house the display and the electronic component, the housing comprising an opening on an outer surface of the housing; a function component partly housed in the housing; a movable part operable through the opening, the movable part configured to slide along the opening between a first position where apart of a function of the function component is restricted and a second position where the restricted part of the function in the first position is released; and a recessed portion or a projecting portion away from the first position when viewed from the second position in a direction along the opening or away from the second position when viewed from the first position in a direction along the opening, the recessed portion or the projecting portion in a circumferential area of the opening.

A plurality of exemplary embodiments and modifications in the following include the same constituent elements. Accordingly, in the following, the same constituent elements are given with common reference numerals, and their redundant explanations are omitted. In appropriate drawings, directions (X direction, Y direction, and Z direction) are indicated for the sake of convenience. The X direction is a longer direction with respect to the frontal view of a display screen of a television receiver, the Y direction is a shorter direction with respect to the frontal view of the display screen, and the Z direction is a front-back direction (depth direction or thickness direction of a housing) with respect to the frontal view of the display screen. The X direction, the Y direction, and the Z direction are orthogonal to one another.

While an electronic device is exemplified to be constructed as a television receiver or as a tablet or a slate personal computer in the following embodiments, the electronic device according to the embodiments is not restricted as such. The electronic device in the embodiments can be constructed as a variety of electronic devices such as a notebook or a desktop personal computer, a smartphone, a smart-television, a smartbook, a cellular phone, a personal digital assistant (PDA), a video display device, and a videophone.

### First Embodiment

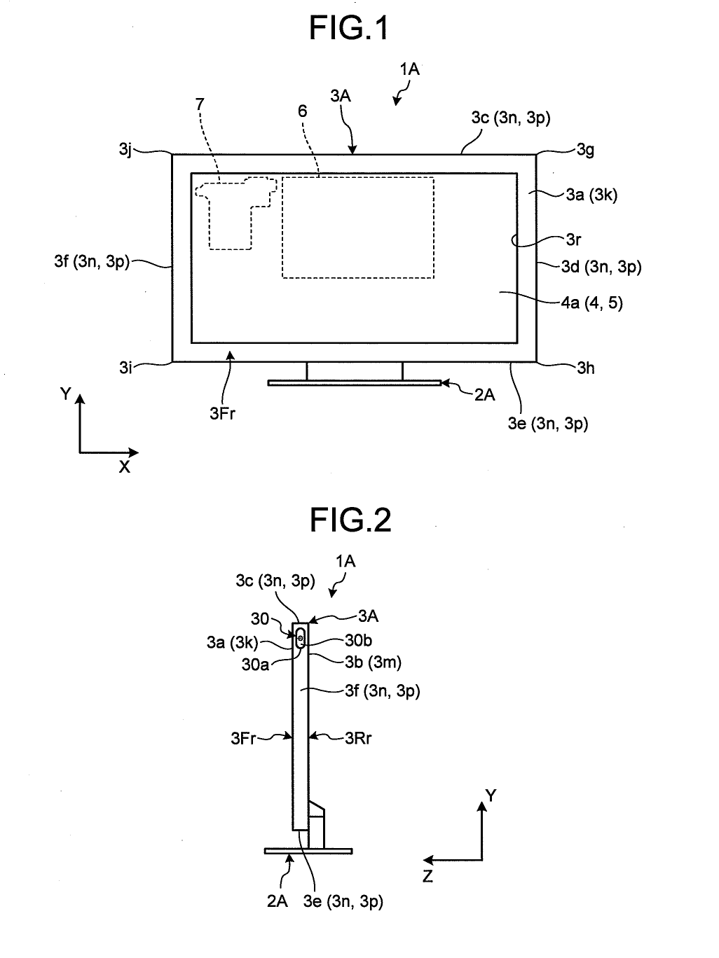

A television receiver 1A that is an example of an electronic device according to a first embodiment, as illustrated in FIGS. 1 and 2, comprises a supporting portion 2A (a support, a pedestal, or a stand) and a housing 3A. A supporting portion 2A is placed on a placing portion such as a desk, a shelf, and a pedestal (a placement surface, not depicted) and supports the housing 3A. The supporting portion 2A may support the housing 3A fixedly, or to be movable (rotational or slidable). Examples of the rotational form of the housing 3A with respect to the supporting portion 2A include tilting, swiveling, and pivoting.

The housing 3A, as illustrated in FIG. 1, is constructed in a square shape (rectangular as an example in the first embodiment) in the frontal view. The housing 3A, as illustrated in FIG. 2, is further constructed in a rectangular parallelepiped shape being thin and flat in the front-back direction. The housing 3A comprises a front surface 3a (a front face, a surface, a first surface, or a first surface portion) and a rear surface 3b (a back face, a surface, a second surface, or a second surface portion) on the opposite side to the front surface 3a. The front surface 3a and the rear surface 3b are approximately parallel to each other. The housing 3A, as illustrated in FIG. 1, in the frontal view, further comprises four ends 3c to 3f (sides or edges) and four corners 3g to 3j (projecting portions, rounded portions, or ends). The ends 3c and 3e are examples of long sides. The ends 3d and 3f are examples of short sides.

The housing 3A further comprises a wall 3k (a first wall, a first portion, a plate, a frame, a front wall, a surface wall, or a top wall) that includes the front surface 3a, and a wall 3m (a second wall, a second portion, a plate, a rear wall, a back wall, or a bottom wall) that includes the rear surface 3b. The walls 3k and 3m are in a square shape (in a rectangular shape as an example in the first embodiment). The housing 3A further comprises four walls 3n (third walls, third portions, plates, side walls, end walls, standing walls, or spanning portions) that include side surfaces 3p (surfaces, circumferential surfaces, or third surfaces) which span between the wall 3k and the wall 3m. On the wall 3k, as an example, an opening 3r in a square shape is provided.

Furthermore, the housing 3A can be constructed with a plurality of components (separate bodies or members) combined. The housing 3A comprises, as an example, a first member 3Fr (a first portion, a front side member, or a cover) that includes at least the wall 3k, and a second member 3Rr (a second portion, a rear side member, a base, or a bottom) that includes at least the wall 3m. The walls 3n can be included in at least one of the first member 3Fr or the second member 3Rr (for example, the second member 3Rr). Moreover, separately from the first member 3Fr and the second member 3Rr, the housing 3A comprises a third member (a third portion, an intermediate member, a partition member, a barrier member, a wall member, an intervening member, an inner plate, a middle plate, or a middle frame, not depicted) positioned in between the foregoing. In this case, the walls 3n can be included in the third member. The housing 3A can be constructed with metallic materials, synthetic resin materials, and such.

In the housing 3A, a display device 4 (a display module, a display, or a panel) is housed. A display screen 4a positioned on the front surface 3a side of the display device 4 is exposed towards the front (outwardly) of the housing 3A through the opening 3r, and a user can view the display screen 4a from the front side through the opening 3r. The display device 4 is constructed in a square shape (in a rectangular shape as an example in the first embodiment) in the frontal view. The display device 4 is further constructed in a rectangular parallelepiped shape being thin and flat in the front-back direction. The display device 4, for example, is a liquid crystal display (LCD), an organic electro-luminescent display (OELD), or the like.

On the front side (a surface side or the wall 3k side) of the display device 4, a transparent and relatively thin square shaped input operation panel 5 (a touch panel, a touch sensor, or an operation surface as an example) is provided. The input operation panel 5 covers the display screen 4a. An operator (a user and such) can execute an input process by performing an operation of touching, pressing, or rubbing the input operation panel 5 with, for example, a finger or a stylus, or moving the finger or the stylus near the input operation panel 5. The light emitted from the display screen 4a of the display device 4 passes through the input operation panel 5 and goes out ahead (outwardly) of the housing 3A from the opening 3r of the wall 3k. The input operation panel 5 is an example of an input module.

In the housing 3A, on the rear side (a reverse side, a back side, the wall 3m side, or an opposite side to the display screen 4a) of the display device 4, a plurality of substrates 6 and 7 (circuit boards) are housed. The substrates 6 and 7 are arranged in positions different from each other and are both provided in parallel with the display device 4. Furthermore, the substrates 6 and 7 are provided in a condition being separated from the walls 3k, 3m, and 3n, more specifically, in a condition where space is formed with the respective walls 3k, 3m, and 3n. It is preferable that the substrates 6 and 7 be arranged side-by-side along the display device 4, not overlapping with each other in a thickness direction of the housing 3A. The substrates 6 and 7 are fixed to the housing 3A with fixing tools, for example, screws.

On the substrates 6 and 7 (first boards, first circuit boards, control boards, or main boards) illustrated in FIG. 1, a plurality of electronic components (components or elements, not depicted) such as a central processing unit (CPU) are mounted. The electronic components include heating elements. On an electronic component (a heating element) of a large heat value, a cooling mechanism (a heat dissipating part or a heat receiving part, not depicted) can be further provided. The substrates 6 and 7 and the electronic components constitute at least a part of a control circuit (not depicted). Examples of the control circuit may include a video signal processing circuit, a tuner, a high-definition multimedia interface (HDMI) signal processor, an audio video (AV) input terminal, a remote control signal receiver, a controller, a selector, an on-screen display interface, a storage module (for example, a read only memory (ROM), a random access memory (RAM), and a hard disk drive (HDD)), and an audio signal processing circuit. The control circuit controls the output of video (for example, movies and still pictures) on the display screen 4a of the display device 4, the output of audio from a speaker (not depicted), light emission of a light emitting diode (LED, not depicted), and such. The display device 4, the speaker, and the LED are examples of output modules.

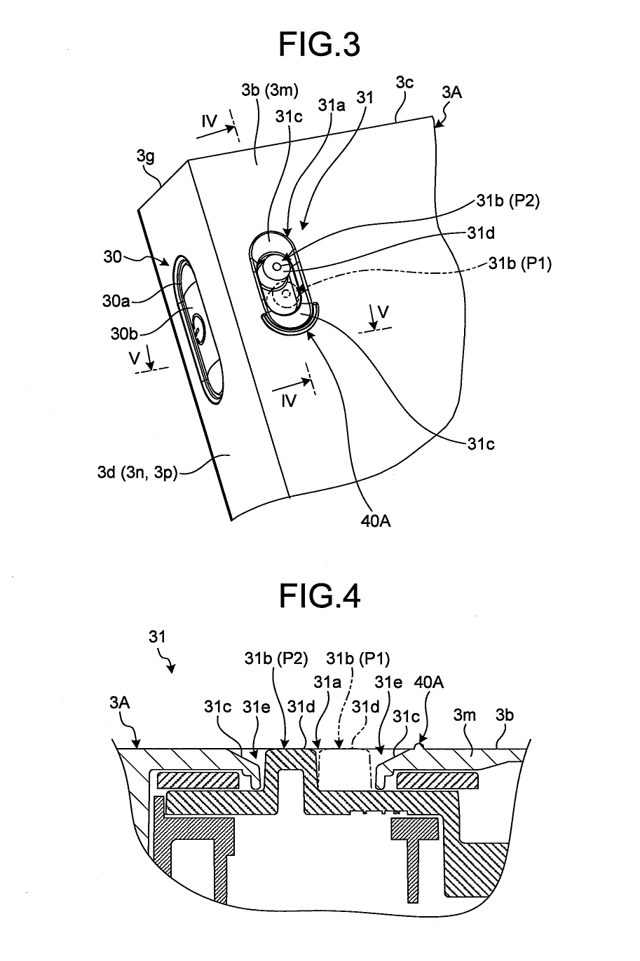

In the first embodiment, as an example, as illustrated in FIGS. 3 and 4, two switches 30 and 31 (operating parts) are provided close to the corner 3g of the housing 3A. Specifically, an opening 30a for the switch 30 is provided to the side surface 3p (a surface or an outer surface) of the wall 3n as an elongated through hole longer in a direction along the end 3d (the Y direction). An opening 31a for the switch 31 is provided to the rear surface 3b (a surface or an outer surface) of the wall 3m as an elongated through hole longer in the direction along the end 3d (the Y direction). The openings 30a and 31a are provided adjacently (correspondingly). In the opening 30a, a movable part 30b (an operator, an operating part, or a button) is housed. The movable part 30b is provided to project and retract (to appear and disappear, to go in and go out, to be movable, or to reciprocate) in a direction crossing the side surface 3p (a normal direction as an example in the first embodiment). In the opening 31a, a movable part 31b (an operator, an operating part, or a slider) is housed. The movable part 31b is provided to reciprocate between a first position P1 and a second position P2 in a direction along the side surface 3p. In the opening 31a, as illustrated in FIG. 4, inclined surfaces 31c are further provided. The inclined surfaces 31c are inclined on the rear surface 3b side in a direction in which the area of the opening expands towards the outside of the housing. By such a configuration, between a top surface 31d (a surface or an apical surface) of the movable part 31b and the rear surface 3b (a surface or an outer surface), a recessed portion 31e including the inclined surfaces 31c and the side surfaces of the movable part 31b is formed. Accordingly, as an example, the operator puts a finger and such in the recessed portion 31e, whereby the movable part 31b is made easier to operate for the operator.

In the first embodiment, as an example, the switch 30 is constructed as a power switch (a power operating part, a power button, a function component, an electrical component, or a component). In this case, for example, pressing the movable part 30b can switch on and off the power to the television receiver 1A. The movable part 30b presses a contacting portion (not depicted) constructed as a push switch, and this causes the power to be switched on and off. In other words, the switch 30 is configured as a push switch.

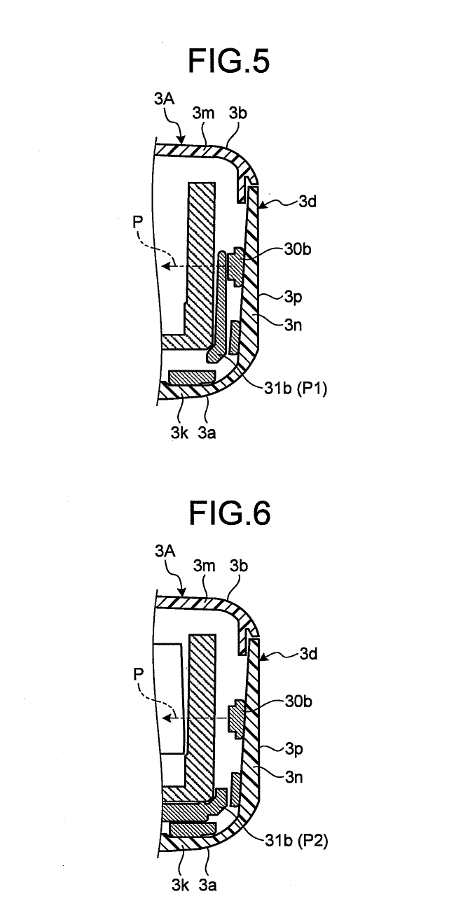

Meanwhile, in the first embodiment, as an example, the switch 31 can serve as an operation locking part (a lock part, a lock, a lock switch, or a lock slider) for the switch 30. Specifically, the movable part 31b in a condition of being positioned on one side (the first position P1 as an example in the first embodiment) suppresses the movement (sinking or retraction) of the movable part 30b, and in a condition of being positioned on the other side (the second position P2 as an example in the first embodiment), permits the movement of the movable part 30b. More specifically, the movable part 31b in a condition of being positioned in the first position P1, i.e., being in a position on a moving path (moving direction P) of the movable part 30b as illustrated in FIG. 5, obstructs the movement of the movable part 30b. In other words, the movable part 31b in a condition of being positioned in the first position P1 restricts the function of the switch 30 as a function component. In a condition of the movable part 31b being in the second position P2, i.e., being in a position off the moving path (moving direction P) of the movable part 30b as illustrated in FIG. 6, the movable part 30b can move in response to an external operation without being obstructed by the movable part 31b. In other words, the movable part 31b in a condition of being in the second position P2 does not obstruct the movement of the movable part 30b. In the first embodiment, as an example, because the position of the contacting portion and the position where the movable part 31b obstructs the movement of the movable part 30b are different, the contacting portion is not depicted in the cross-sectional views in FIGS. 5 and 6.

In the first embodiment, as an example, as illustrated in FIGS. 3 and 4, provided is a movement suppressing portion 40A (a slide suppressing portion, an operation suppressing portion, or a suppressing portion) that suppresses movement of the switch 31 toward the second position P2 from the first position P1 that is where the switch 30 is locked by the switch 31. In the first embodiment, as an example, the movement suppressing portion 40A is provided as a projecting portion (a protruding portion, a boss, a wall portion, or a stepped portion) projecting from the rear surface 3b. The movement suppressing portion 40A is provided in an arc shape (in a semicircle or in a curved line) along the edge of the opening 31a in an arc shape (in a semicircle). The movement suppressing portion 40A is provided in a circumferential area of the opening 31a at a position further away from the first position P1 viewed from the second position P2 side. Accordingly, as an example, when a finger and such of the operator is moved along the rear surface 3b of the housing 3A, the finger and such can be suppressed to contact the movable part 31b by the movement suppressing portion 40A. More specifically, the movement suppressing portion 40A can suppress sliding (movement) of the movable part 31b positioned in the first position P1 (one side) of the opening 31a toward the second position P2 (the other side). Examples of the functional effects of the movement suppressing portion 40A include the following: the movement of the finger and such is physically obstructed; and the operator is made to distinguish tactilely that the movement suppressing portion 40A is different from the rear surface 3b by the finger and such contacting the movement suppressing portion 40A and to realize that, for example, it is better not to move the finger and such any further. Consequently, in the first embodiment, as an example, by the movement suppressing portion 40A being provided as a projecting portion, the movable part 31b is suppressed to move from the first position P1 toward the second position P2. In other words, an erroneous operation or an unintentional operation of the movable part 31b can be suppressed. Accordingly, in the case of the first embodiment, a condition in which the movable part 31b is moved toward the second position P2 where the lock of the switch 30 is released and the switch 30 is operable as a power switch is suppressed. In other words, a condition in which the power can be switched off unintentionally is suppressed. In addition, a movement suppressing portion can be provided in the circumferential area of the opening 31a at a position further away from the second position P2 viewed from the first position P1 side, in other words, at a position on an opposite side of the movement suppressing portion 40A with respect to the opening 31a. In this case, by the movement suppressing portion, the movable part 31b is suppressed to move from the second position P2 toward the first position P1. The movement suppressing portion can be further provided to both sides in the sliding direction (moving direction) of the movable part in the opening 31a.

Furthermore, in the first embodiment, as an example, as illustrated in FIG. 4, the top surface 31d of the movable part 31b is set lower than the movement suppressing portion 40A as a projecting portion and is further set equal to or lower than the rear surface 3b. Therefore, in accordance with the first embodiment, as an example, compared with when the movable part 31b is projecting higher than the rear surface 3b or the movement suppressing portion 40A, the movable part 31b can be further suppressed to move from the first position P1 toward the second position P2.

The movement suppressing portion 40A is preferably provided at a position appropriately separated from the movable part 31b positioned in the first position P1 (for example, at a position separated from the movable part 31b in the first position P1 by a distance of 0.2 to 1.5 times the diameter (width, breadth, or thickness) of the movable part 31b). This is because that the movable part 31b becomes difficult to operate when the movement suppressing portion 40A is too close to the movable part 31b, and when the movement suppressing portion 40A is too far away from the movable part 31b, the effect of movement suppression by the movement suppressing portion 40A diminishes.

In the first embodiment, as an example, as described in the foregoing, the movement suppressing portion 40A surrounds the movable part 31b positioned in the first position P1 from one side (the edge (end or verge) of the opening 31a on one side). Consequently, in accordance with the first embodiment, as an example, a finger and such contacting the movable part 31b from a wider area can be suppressed.

In the first embodiment, as an example, the switches 30 and 31 (the openings 30a and 31a) are provided to the end 3d and at the corner 3g of the housing 3A. Therefore, in accordance with the first embodiment, as an example, it is easier to suppress the interference with other components in the housing 3A. Furthermore, it is easier to achieve a configuration in which the switches 30 and 31 interact with each other (the configuration of the movable part 31b suppressing the movement of the movable part 30b). Moreover, compared with when the switches 30 and 31 are provided at a central part on the rear surface 3b, it is easier for the user to operate them from the front surface 3a side (frontal side).

In the first embodiment, as an example, the switches 30 and 31 (the movable parts 30b and 31b) are provided to the surfaces of the housing 3A different from each other (the side surface 3p and the rear surface 3b). Accordingly, the incidents of operating the switch 30 when the switch 31 is operated or erroneously operating the switch 31 when the switch 30 is operated are likely to be reduced.

The inclined angles of the inclined surfaces 31c can be differentiated for the first position P1 side and for the second position P2 side. As an example, the inclined angle of the inclined surface 31c on the second position P2 side (the inclined surface 31c on the left in FIG. 4) can be set to be more moderate (a condition of an angle with the rear surface 3b being small) than that of the inclined surface 31c on the first position P1 side (the inclined surface 31c on the right in FIG. 4). In this case, as an example, the recessed portion 31e formed by the movable part 31b positioned in the first position P1 and the inclined surface 31c is narrower than the recessed portion 31e formed by the movable part 31b positioned in the second position P2 and the inclined surface 31c. Accordingly, as an example, it becomes harder to put a finger and such of a user in the recessed portion 31e formed by the movable part 31b positioned in the first position P1 and the inclined surface 31c, whereby the movable part 31b is further suppressed to move from the first position P1 to the second position P2. Furthermore, when the top surface 31d is constructed in a shape having a curved surface projecting in a direction away from the rear surface 3b, the recessed portion 31e becomes wider and the movable part 31b is made easier to be operated.

### Second Embodiment

An electronic device 1B according to a second embodiment is, for example, a personal computer, a television receiver, a smartphone, a smartbook, a cellular phone, and a PDA of a so-called slate type, a tablet type, or a display device that includes a software keyboard function.

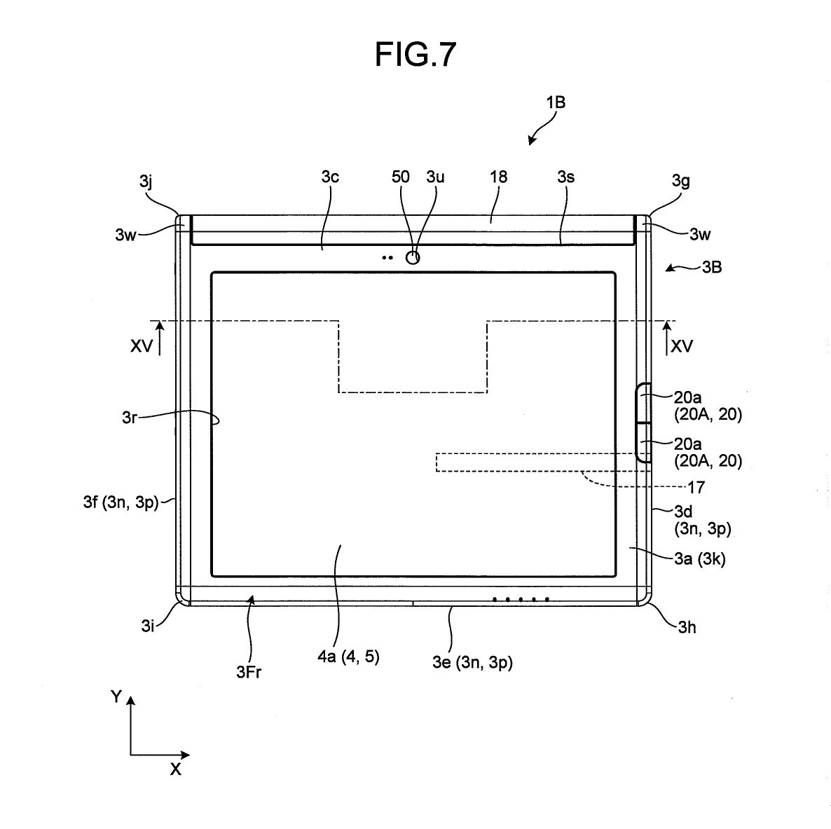

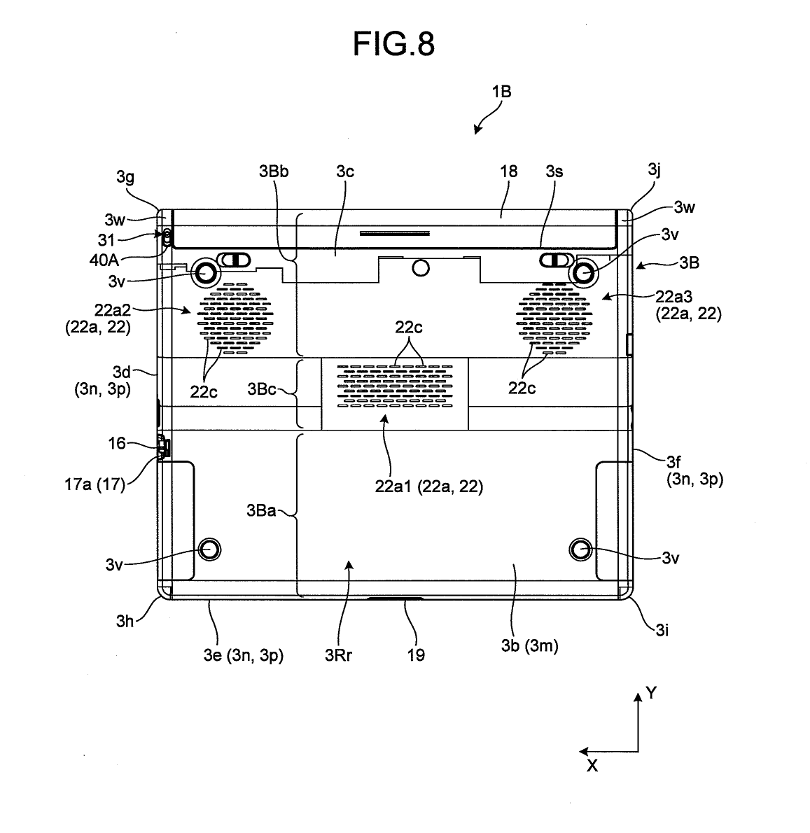

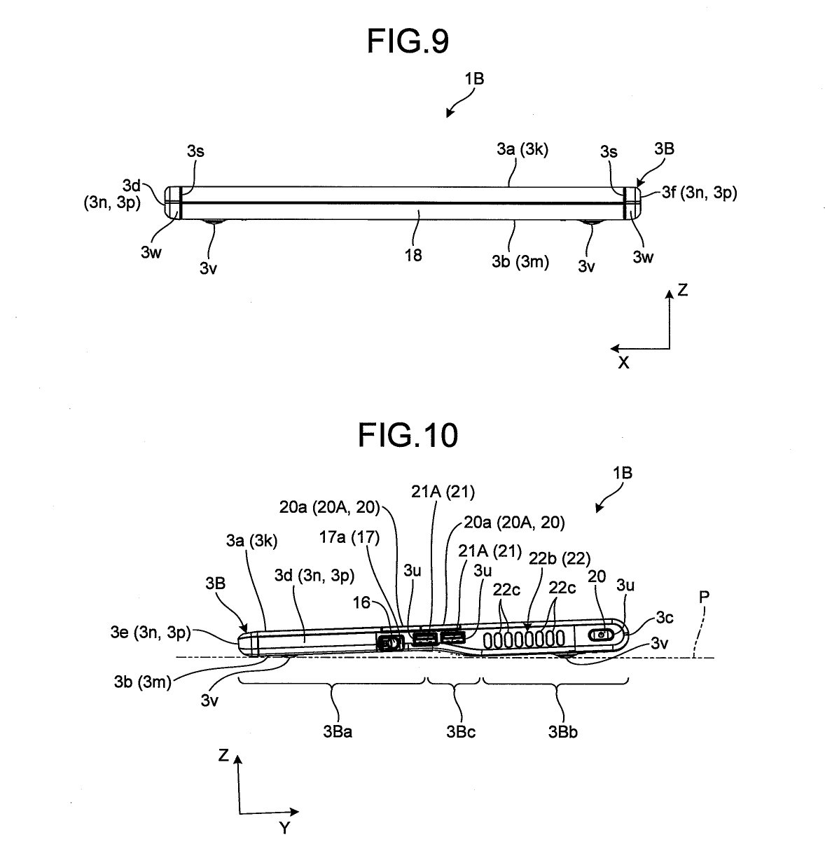

A housing 3B of the electronic device 1B, as illustrated in FIGS. 7 and 8, is constructed in a square shape (in a rectangular shape as an example in the second embodiment) in the frontal view and the back view. The housing 3B, as illustrated in FIGS. 9 to 12, is constructed in a rectangular parallelepiped shape being thin and flat in the front-back direction. The housing 3B comprises the front surface 3a (a front face, a surface, a first surface, or a first surface portion) and the rear surface 3b (a back face, a surface, a second surface, or a second surface portion) on the opposite side to the front surface 3a. The front surface 3a and the rear surface 3b are approximately parallel to each other. The housing 3B, as illustrated in FIGS. 7 and 8, in the frontal view, further comprises the four ends 3c to 3f (sides or edges) and the four corners 3g to 3j (projecting parts, rounded parts, or ends). The ends 3c and 3e are examples of long sides. The ends 3d and 3f are examples of short sides.

The housing 3B further comprises the wall 3k (a first wall, a first portion, a plate, a frame, a front wall, a surface wall, or a top wall) that includes the front surface 3a, and the wall 3m (a second wall, a second portion, a plate, a rear wall, a back wall, or a bottom wall) that includes the rear surface 3b. The walls 3k and 3m are in a square shape (in a rectangular shape as an example in the second embodiment). The housing 3B further comprises the four walls 3n (third walls, third portions, plates, side walls, end walls, standing walls, or spanning portions) that include the side surfaces 3p (surfaces, peripheral surfaces, or third surfaces) which span between the wall 3k and the wall 3m. In the wall 3k, as an example, the opening 3r in a square shape is provided.

Furthermore, the housing 3B can be constructed with a plurality of components (separate bodies) combined. The housing 3B comprises, as an example, the first member 3Fr (a first portion, a front side member, or a cover) that includes at least the wall 3k, and the second member 3Rr (a second portion, a rear side member, a base, or a bottom) that includes at least the wall 3m. The walls 3n are included in at least one of the first member 3Fr or the second member 3Rr (for example, the second member 3Rr). Moreover, in the second embodiment, as illustrated in FIG. 13, separately from the first member 3Fr and the second member 3Rr, the housing 3B comprises a third member 3Md (a third portion, an intermediate member, a partition member, a barrier member, a wall member, an intervening member, an inner plate, a middle plate, or a middle frame) positioned in between the foregoing. A part of the walls 3n can be included in the third member 3Md. The housing 3B can be constructed with metallic materials and synthetic resin materials. As an example, the second member 3Rr and the third member 3Md can be constructed with metallic materials such as magnesium alloy, and the first member 3Fr can be constructed with synthetic resin materials that have a lower rigidity than the second member 3Rr and the third member 3Md. On the first member 3Fr, the second member 3Rr, and the third member 3Md, wall portions such as ribs (projecting portions or projecting walls) can be provided. By the wall portions, the rigidity of the housing 3B is improved. On the third member 3Md, openings such as through holes can be provided. By the openings, the housing 3B can be constructed to be lighter.

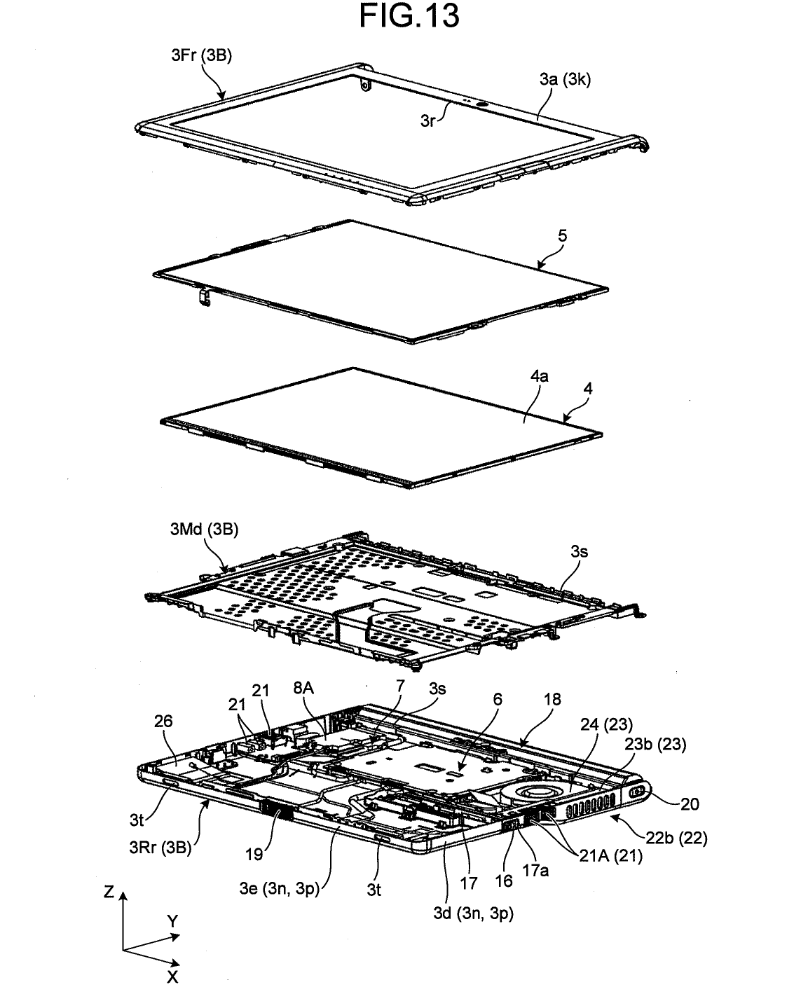

In the second embodiment, as illustrated in FIGS. 10 and 12, as an example, the thickness of a first part 3Ba that is positioned on a downside or a near side (closer to a user) in a use condition where the longer direction of the electronic device is positioned sideways is thinner than that of a second part 3Bb that is positioned on an upper side or a back side (far from the user) in the use condition. Therefore, in a use condition where the electronic device is placed on a placement surface P such as a desk, the height of the front surface 3a of the housing 3B and that of the display screen 4a from the placement surface P become higher towards the back side (upside) from the near side (downside). Consequently, in accordance with the second embodiment, as an example, the display screen 4a is in a so-called tilted state for the user positioned on the left side in FIG. 10 or on the right side in FIG. 12 with respect to the electronic device 1B, and thus the user is advantageously easy to view the display screen 4a.

Furthermore, the direction of video output on the display screen 4a when in use can be changed corresponding to the position of the housing 3B (the electronic device 1B). For example, a control circuit provided in the housing 3B (not depicted) can change the direction, size, and such of the video output on the display screen 4a in response to the detection result of a sensor (for example, a gyro sensor and an acceleration sensor) provided to the housing 3B. The control circuit can further limit the position of video to some positions. Specifically, for example, the control circuit can display the video the top of which is on the end 3c side on the display screen 4a when the end 3c of the housing 3B is positioned on the upper side than the end 3e (a first position), and when the end 3d is positioned on the upper side than the end 3f (a second position), the control circuit can display the video the top of which is on the end 3d side on the display screen 4a. When the position of the housing 3B is changed from a previous position to the first position or the second position, the control circuit switches the video on the display screen 4a to the video corresponding to the position. However, when the position of the housing 3B is changed from a previous position to a position other than the first position or the second position (more specifically, in this example, the position where the end 3e is positioned on the upper side than the end 3c or the position where the end 3f is positioned on the upper side than the end 3d), the control circuit does not switch the video on the display screen 4a. By such control, the use position of the electronic device 1B by the user can be limited.

To the housing 3B, a component storage 17 that houses a component 16 to be taken in and out is provided. An opening 17a of the component storage 17 in the second embodiment, as an example, is opened to the end 3d. The opening 17a is provided to the end 3d that is set on the upside in any of the use positions (in the above-described example, the first position or the second position) and is not set on the downside in non-use positions. According to such a configuration, the opening 17a is positioned on the upside in the use positions. Consequently, as an example, it makes it easy to suppress falling off of the component 16 to from the component storage 17 due to the action of gravity. The component 16 is specifically, for example, a stylus, a stylus pen, and a pen.

Furthermore, as illustrated in FIG. 7, in the second embodiment, a battery 18 and the display device 4 are not overlapped with each other in the thickness direction of the housing 3B and are arranged in juxtaposition in a direction orthogonal to the thickness direction (a direction along the front surface 3a or the rear surface 3b, the X direction, or the Y direction, and the Y direction as an example in the second embodiment). Accordingly, as an example, compared with when the battery 18 and the display device 4 are overlapped in the thickness direction of the housing 3B, the housing 3B can be constructed thinner. Furthermore, as an example, compared with when the battery 18 and the display device 4 are overlapped in the thickness direction of the housing 3B, it makes it easy not only to make the battery 18 thicker, but also to increase the capacity of the battery 18 per unit volume. Moreover, as illustrated in FIGS. 10 and 12, in the second embodiment, the housing 3B comprises the thin first part 3Ba and the thick second part 3Bb. A battery storage 3s (a battery supporting portion) that houses the battery 18 is provided to the end 3c of the thick second part 3Bb. Consequently, as an example, compared with when the battery storage 3s is provided to the first part 3Ba, it makes it easy not only to make the battery thick, but also to increase the storage capacity of the battery 18 per unit volume.

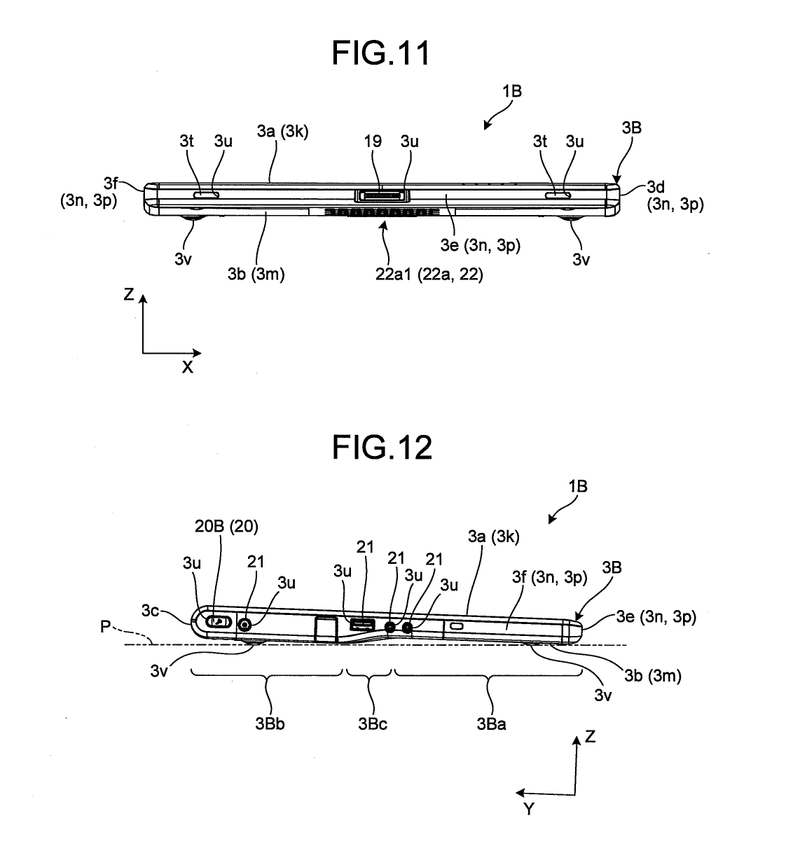

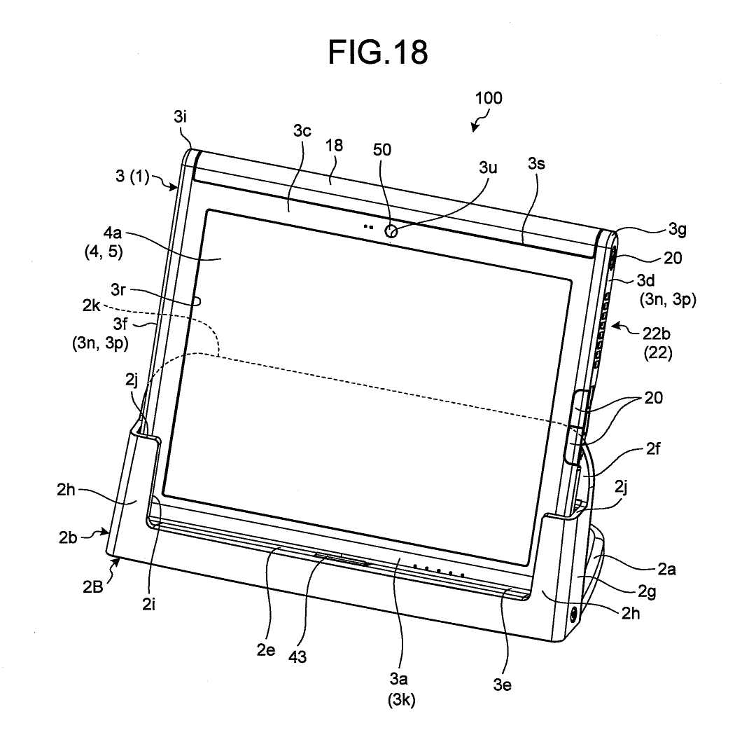

In the second embodiment, the end 3e on the opposite side of the end 3c where the battery storage 3s is provided is supported on a stand (other electronic device or a docking station, see FIG. 18). Accordingly, as an example, a worker (a user and such) can attach and detach the battery 18 to and from the housing 3B under a condition of the electronic device 1B being supported on a stand 2B. On the end 3e, as illustrated in FIG. 11, a connector 19 is provided to be connected with a connector 43 of the stand 2B. Accordingly, as an example, the battery storage 3s and the connector 19 are easily provided to the housing 3B without interfering with each other. On the end 3e, terminals 3t are also exposed. The connector 19 and the terminals 3t are exposed through openings 3u provided to the wall 3n of the end 3e.

As illustrated in FIG. 18, the stand 2B comprises a first supporting portion 2a extending along the placement surface P (see FIGS. 10 and 12) and a second supporting portion 2b extending in a direction crossing the placement surface P. The stand 2B further comprises walls 2f, 2g, and 2h that surround the end 3d of the housing 3B. The wall 2h is provided with an opening 2i (a cutout). The housing 3B, in the condition being supported on the stand 2B, the portions (upper side portions) further away from the placement surface P than ends 2j and 2k (upper ends) of the walls 2f, 2g, and 2h are exposed from the stand 2B.

In the battery storage 3s, the portions hidden by the battery 18 are provided with connecting portions of any two or more (two or three) of the first member 3Fr, the second member 3Rr, and the third member 3Md of the housing 3B. In the connecting portion, for example, by a screw (not depicted) as an example of a connecting tool, the first member 3Fr is connected with the third member 3Md or the second member 3Rr. When disassembling the housing 3B, the worker (user and such) first removes the screw, and locally separates the first member 3Fr and the third member 3Md or the second member 3Rr at this portion to set them apart. The worker then, for example, while applying a force to the portion separated and resiliently deforming the first member 3Fr, releases the connection of a resilient connecting portion (an engaging portion or a coupling portion, as an example, an engaging portion by a claw and an edge of a hole, not depicted) of the first member 3Fr with the third member 3Md or the second member 3Rr to remove the first member 3Fr from the third member 3Md or the second member 3Rr. A plurality of connecting portions (engaging portions or coupling portions) connecting the first member 3Fr with the third member 3Md or the second member 3Rr are provided along the outer circumference of the first member 3Fr. A plurality of screws (not depicted) as connecting tools to connect the second member 3Rr and the third member 3Md are all covered by the first member 3Fr. Therefore, the worker removes the first member 3Fr from the third member 3Md or the second member 3Rr so that the screws can be removed to separate the third member 3Md and the second member 3Rr. According to such a configuration, when the battery 18 is removed from the battery storage 3s, the housing 3B can be disassembled smoothly. In other words, the housing 3B to be disassembled in a condition of the battery 18 being attached to the battery storage 3s can be suppressed.

In the second embodiment, the second member 3Rr and the third member 3Md extend to the battery storage 3s and constitute a part of the end 3c (the wall 3n or the side surface 3p). Accordingly, as an example, the rigidity of the housing 3B can be made higher. Because the rigidity of the battery storage 3s becomes higher, as an example, it makes it easy to further suppress the vibration, misalignment, and such of the battery 18.

As illustrated in FIGS. 7 to 12, on the front surface 3a and the side surface 3p of the housing 3B, operating parts 20 and connectors 21 are provided. The operating parts 20 can be push buttons, push switches, slide switches, pointing devices, and such. The connectors 21 are a connector for power cable, USB connectors, connectors for earphone and microphone, and the like. The operating parts 20 and the connectors 21 are exposed through the openings 3u provided to the walls 3k and 3n of the housing 3B. On the front surface 3a, a camera 50 (a camera module or an imaging device) can be provided.

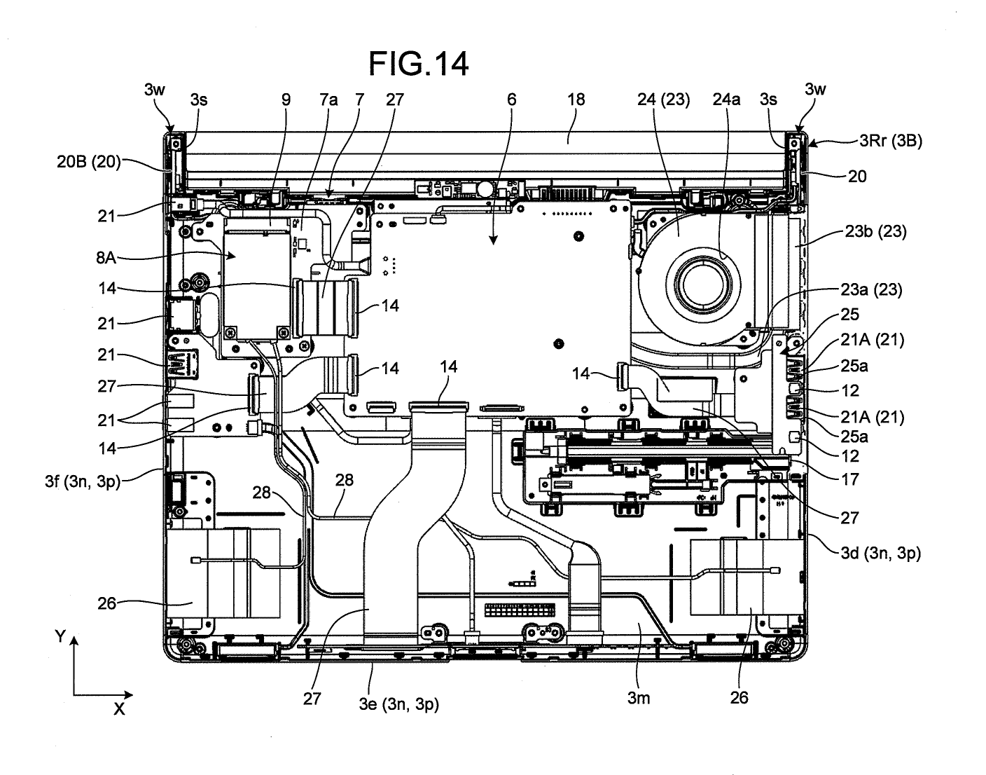

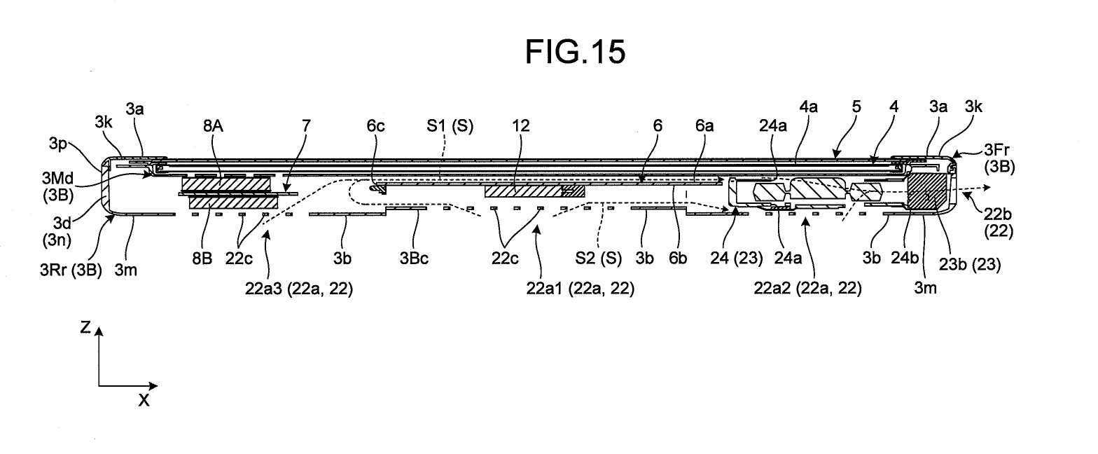

As illustrated in FIGS. 8 and 10, on the rear surface 3b and the side surface 3p of the housing 3B, ventilation holes 22 that introduce or exhaust air used for cooling electronic components 12 and such (see FIG. 15, for example) are provided. In the second embodiment, as an example, on the rear surface 3b (the wall 3m), inlets 22a that introduce air are provided, and on the side surface 3p (the wall 3n or the end 3d), an exhaust outlet 22b is provided. In the second embodiment, the inlets 22a and the exhaust outlet 22b are provided as collective portions of small openings 22c provided to the walls 3m and 3n. Additionally, on the rear surface 3b, protruding portions 3v (for example, protruding portions made of rubber and such) are provided. Accordingly, even in a condition where the rear surface 3b is placed on the placement surface P, the inlets 22a are not blocked. In the second embodiment, in a border portion between the thin first part 3Ba and the thick second part 3Bb, an inclined portion 3Bc is provided. As illustrated in FIG. 8, one inlet 22a1 out of the inlets 22a is provided in the inclined portion 3Bc on the rear surface 3b. As illustrated in FIGS. 10 and 12, because the distance between the inclined portion 3Bc and the placement surface P becomes larger than the distance between the other portions and the placement surface P, an airflow resistance for the inlet 22a1 provided in the inclined portion 3Bc is likely to be reduced, whereby cooling efficiency is made easier to increase. In the second embodiment, a plurality of inlets 22a are provided. Accordingly, as an example, even when one of the inlets 22a is blocked for some reason, the air can be introduced in the housing 3B from the other inlets 22a, whereby the cooling efficiency is not likely to be impaired. The inside of the housing 3B may be cooled by a cooling mechanism 23 (see FIG. 14, for example) or may be cooled by natural cooling (convective cooling).

As illustrated in FIG. 13, in the second embodiment, in the housing 3B, as an example, between the first member 3Fr and the third member 3Md, the display device 4 (a display module, a display, or a panel) is housed. The display screen 4a positioned on the front surface 3a of the display device 4 is exposed towards the front (outwardly) through the opening 3r, and the user can view the display screen 4a from the front side through the opening 3r. The display device 4 is constructed in a square shape (a rectangular shape as an example in the second embodiment) in the frontal view. The display device 4 is further constructed in a rectangular parallelepiped shape being thin and flat in the front-back direction. The display device 4, for example, is a liquid crystal display (LCD), an organic electro-luminescent display (GELD), or the like.

Furthermore, on the front side (a surface side or the wall 3k side) of the display device 4, the transparent and relatively thin square shaped input operation panel 5 (a touch panel, a touch sensor, or an operation surface as an example) is provided. The input operation panel 5 covers the display screen 4a. An operator (a user and such) can execute an input process by performing an operation such as touching, pressing, or rubbing the input operation panel 5 with, for example, a finger or the component 16 (a stylus), or moving the finger or the stylus near the input operation panel 5. The light emitted from the display screen 4a of the display device 4 passes through the input operation panel 5 and goes out ahead (outwardly) of the housing 3B from the opening 3r of the wall 3k. The input operation panel 5 is an example of an input module.

As illustrated in FIGS. 13 and 14, in the housing 3B, on the rear side (a reverse side, a back side, the wall 3m side, an opposite side to the display screen 4a) of the display device 4, in the second embodiment, as an example, between the second member 3Rr and the third member 3Md, a plurality of substrates 6, 7, and 25 are housed. The substrates 6, 7, and 25 are arranged in positions different from one another and are all provided in parallel with the display device 4. Furthermore, the substrates 6, 7, and 25 are provided in a condition being separated from the walls 3k, 3m, and 3n, more specifically, in a condition where space is formed with the respective walls 3k, 3m, and 3n. It is preferable that the substrates 6, 7, and 25 be arranged side-by-side along the display device 4, not overlapping with one another in the thickness direction of the housing 3B. The substrates 6, 7, and 25 are fixed to the housing 3B with fixing tools, for example, screws.

On the substrate 6 (a first board, a first circuit board, a control board, or a main board), for example, the plurality of electronic components 12 can be mounted (see FIG. 15, for example; only a part of the components are depicted in FIG. 15), such as a central processing unit (CPU), a graphic controller, power supply circuit components, a platform controller hub (PCH), a memory slot connector, an LCD connector, an input/output (I/O) connector, a power coil, elements, and connectors. The electronic components 12 include heating elements. On an electronic component 12 of a large heat value (a heating element), the cooling mechanism 23 can be provided. The cooling mechanism 23 comprises a heat sink (a heat receiving part, not depicted), a heat pipe 23a, a heat dissipating part 23b, and a fan 24. The substrate 6 and the electronic components 12 constitute at least a part of a control circuit (not depicted). Examples of the control circuit may include a video signal processing circuit, a tuner, a high-definition multimedia interface (HDMI) signal processor, an audio video (AV) input terminal, a remote control signal receiver, a controller, a selector, an on-screen display interface, a storage module (for example, a read only memory (ROM), a random access memory (RAM), and a hard disk drive (HDD)), and an audio signal processing circuit. The control circuit controls the output of video (for example, movies and still pictures) on the display screen 4a of the display device 4, the output of audio from a speaker (not depicted), light emission of a light emitting diode (LED, not depicted), and such. The display device 4, the speaker, and the LED are examples of output modules.

The substrate 7 and modules 8A and 8B have the same configuration as that in the above-described first embodiment. In the second embodiment, a first surface 7a of the substrate 7 and the module 8A are positioned on the display device 4 side, and a second surface 7b and the module 8B are positioned on the opposite side of the display device 4. The first surface 7a, the second surface 7b, and the modules 8A and 8B are arranged along the display device 4. On the substrate 25, the electronic components 12 are provided. In the housing 3B, flexible cables 27 are provided. The flexible cables 27 electrically connect among the substrates 6, 7, and 25, the display device 4, the connector 19, and such. The flexible cables 27 are electrically connected to corresponding connectors 14. The flexible cables 27 are, for example, flexible printed wiring boards and flat cables.

As illustrated in FIG. 14, in the housing 3B, a plurality of antennas 26 are housed. In the second embodiment, the plurality of antennas 26 connected with a single communication module (for example, the module 8B) are arranged separately from one another. In the second embodiment, as an example, one of the antennas 26 is arranged near the end 3d and the end 3e (near the corner 3h) of the housing 3B, while the other one of the antennas 26 is arranged near the end 3e and the end 3f (near the corner 3i) of the housing 3B. Accordingly, as an example, space diversity by the antennas 26 can be configured. The antennas 26 and the module 8B are electrically connected via cables 28. Furthermore, the function of the antennas 26 can be allotted such that one of the antennas 26 is assigned for transmitting and receiving while the other one of the antennas 26 is assigned for receiving only, or one of the antennas 26 can be used as a spare for the other one of the antennas 26.

As is clear from FIGS. 8 and 13, the substrates 6 and 7 and the cooling mechanism. 23 are positioned in the thick second part 3Bb of the housing 3B. Accordingly, as an example, compared with when the substrates 6 and 7 and the cooling mechanism 23 are positioned in the thin first part 3Ba, it is easier to secure a wider space, and thus the cooling effect by the airflow flowed by the fan 24 of the cooling mechanism 23 can be obtained easily. In the second embodiment, the fan 24 and the heat dissipating part 23b are provided at the corner 3g where the end 3c and the end 3d are connected and that is positioned on the upper side in specified (controlled) use conditions. Therefore, as an example, regardless of the use positions of the electronic device 1B, the fan 24 and the cooling mechanism 23 can be arranged on the upper side in the housing 3B. Accordingly, as an example, heat is not likely to remain inside the housing 3B. The fan 24 and the heat dissipating part 23b are provided adjacent to the exhaust outlet 22b.

The substrate 7 is provided at the position where the substrate 6 is sandwiched with the cooling mechanism 23 (the positions in the second part 3Bb where the substrate 7, the substrate 6, and the cooling mechanism 23 are arranged in order of the foregoing). By such a configuration, the air taken in from the outside hits the substrate 7 before reaching the position of the substrate 6. Accordingly, as an example, the heat dissipation efficiency of the substrate 7 is improved. The substrate 7 mounted with the modules 8A and 8B is relatively heavy in weight out of the components in the housing 3B, and with respect to the substrate 6 positioned in the center of the housing 3B, is positioned on the opposite side of the cooling mechanism 23 that is another heavy component. Accordingly, as an example, the weight balance of the electronic device 1B becomes better. Consequently, as an example, when carrying the electronic device 1B, it is easier to hold for the user.

As illustrated in FIGS. 8 and 15, in the second embodiment, as an example, on the wall 3m of the housing 3B, an inlet 22a2 close to the fan 24, an inlet 22a3 positioned on the opposite side of the inlet 22a2 across the substrate 6, and the inlet 22a1 closer to the electronic components 12 as heat elements than the inlets 22a2 and 22a3 are provided. The inlet 22a2 being provided allows airflow to flow into the housing 3B more efficiently. Furthermore, an airflow S introduced from the inlet 22a3 is divided into an airflow S2 that flows towards the fan 24 along a second surface 6b on the rear side of the substrate 6 and an airflow S1 that passes through (goes around or detours) the outside of an end 6c of the substrate 6 positioned on the opposite side of the fan 24 and flows towards the fan 24 along a first surface 6a on the front side of the substrate 6. Consequently, the electronic components 12 (heating elements) provided to both the first surface 6a and the second surface 6b of the substrate 6 can be cooled.

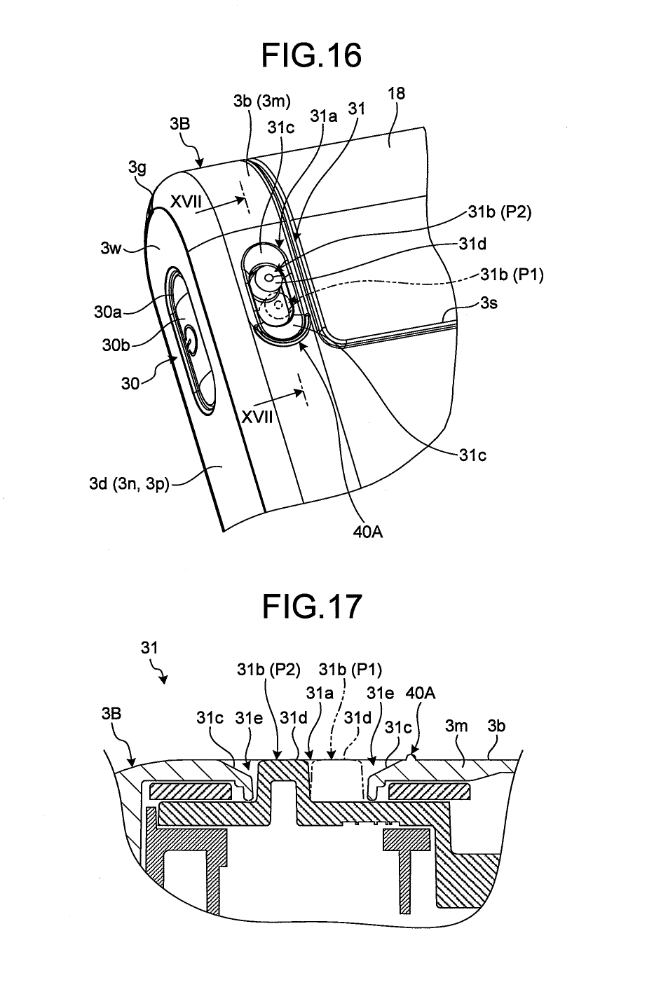

In the second embodiment, as an example, as illustrated in FIGS. 16 and 17, the switches 30 and 31 and the movement suppressing portion 40A having the same configuration as that of the above-described first embodiment are provided. Although the external form of the housing 3B is slightly different, the configuration and arrangement of the switches 30 and 31 are the same as those in the first embodiment. Therefore, by the second embodiment, the same effect as that in the first embodiment for the switches 30 and 31 by the movement suppressing portion 40A can be obtained.

In the second embodiment, as an example, as illustrated in FIG. 16, the switches 30 and 31 are provided inside a supporting portion 3w (a projecting portion) that is provided at the end of the battery storage 3s, which supports the battery 18, in the longer direction thereof. By such a configuration, as an example, a dead space in this portion can be used more effectively.

In the second embodiment, as an example, the protruding portions 3v protruding higher than the movement suppressing portion 40A provided as a projecting portion (a protruded portion) are provided. Accordingly, even when the housing 3B is moved in a condition where the housing 3B is placed on the placement surface P as illustrated in FIG. 10, or when the housing 3B is put in a bag, by the protruding portions 3v in addition to the movement suppressing portion 40A, the movable part 31b being moved unintentionally is suppressed. Furthermore, one of the protruding portions 3v near the movement suppressing portion 40A is positioned on the side where the movement suppressing portion 40A is positioned and away from the movement suppressing portion 40A as viewed from the movable part 31b positioned in the first position P1. Accordingly, the protruding portion 3v can strengthen the effect of movement suppression for the movable part 31b by the movement suppressing portion 40A. In the second embodiment, as an example, as illustrated in FIG. 8, the protruding portion 3v is arranged near the switch 31 and the movement suppressing portion 40A. Therefore, in accordance with the second embodiment, as an example, the effect by the protruding portion 3v is easily obtainable. In the second embodiment, as an example, the switch 31 and the movement suppressing portion 40A are positioned closer to the end 3d and the corner 3g than the protruding portion 3v. Consequently, in accordance with the second embodiment, as an example, the operation of the switch 31 (the movable part 31b) from the frontal side of the housing 3B is not likely to be obstructed.

As can be appreciated from FIGS. 8 and 18, in the second embodiment, as an example, the switch 31 (the movable part 31b) and the movement suppressing portion 40A are provided to the portion exposed from the stand 2B in a condition of the housing 3B being supported on the stand 2B, more specifically, on the end 3c on the opposite side of the end 3e where the connector 19 is provided or on the corner 3g. Accordingly, as an example, when the housing 3B is attached or detached to or from the stand 2B, the movable part 31b being moved by hitting the stand 2B and such is suppressed.

The switch 31 (the movable part 31b) can be provided to a curved portion of the housing 3B. In this case, because the movable part 31b can be provided at a position further away from the rear surface 3b (a surface), when the housing 3B is placed on the placement surface P, the movable part 31b being moved by hitting the placement surface P and such is suppressed. While the opening 31a of the switch 31 (the longer direction thereof or the moving direction of the movable part 31b) in the second embodiment, as an example, is set along the shorter direction of the housing 3B (the attaching and detaching direction to and from the stand 2B), it may be set along the longer direction of the housing 3B.

### First Modification

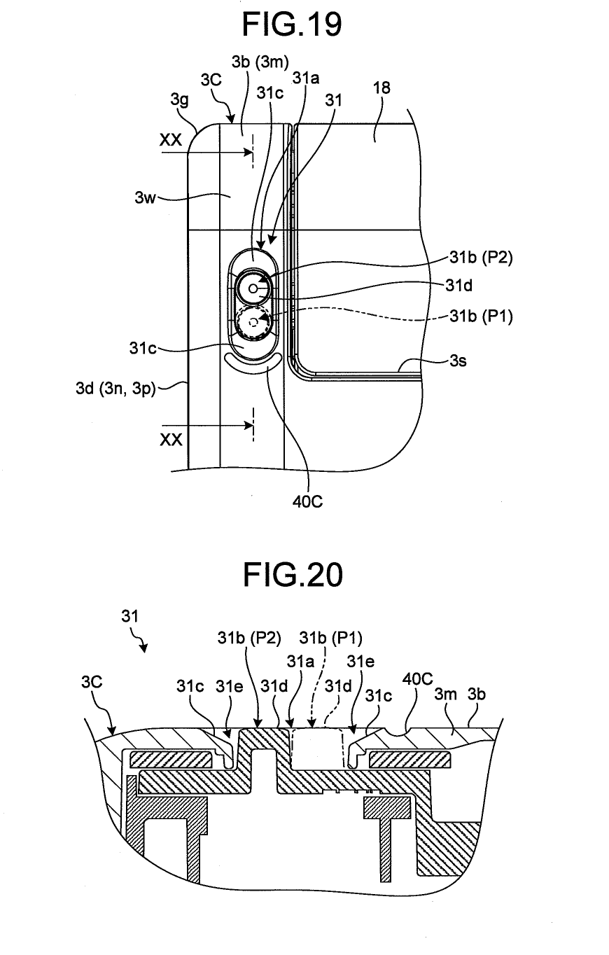

In a first modification, as an example, as illustrated in FIGS. 19 and 20, a movement suppressing portion 40C replaces the movement suppressing portion 40A in the first and the second embodiments in the foregoing. The first modification is the same as the second embodiment, except that the movement suppressing portion 40C replaces the movement suppressing portion 40A. The movement suppressing portion 40C, as an example, is provided as a recessed portion (a recessed groove, a hole, an opening, or a stepped portion). The movement suppressing portion 40C is an example of an irregular portion. The movement suppressing portion 40C is also provided in an arc shape (in a semicircle or in a curved line) along the edge of the opening 31a in an arc shape (in a semicircle). Accordingly, as an example, when a finger and such of the operator is moved along the rear surface 3b of a housing 3C, the finger and such can be suppressed to contact the movable part 31b by the movement suppressing portion 40C. More specifically, the movement suppressing portion 40C can suppress sliding (movement) of the movable part 31b positioned in the first position P1 (one side) of the opening 31a toward the second position P2 (the other side). Examples of the functional effects of the movement suppressing portion 40C include the following: the movement of the finger and such is physically obstructed (for example, catching an edge of the recessed portion with the finger and such); and the operator is made to distinguish tactilely that the movement suppressing portion 40A is different from the rear surface 3b by the finger and such contacting the movement suppressing portion 40C and to realize that, for example, it is better not to move the finger and such any further. Consequently, in the first modification, as an example, by the movement suppressing portion 40C being provided as a recessed portion, the movable part 31b is suppressed to move from the first position P1 toward the second position P2. In other words, an erroneous operation or an unintentional operation of the movable part 31b by the operator can be suppressed. Even by the first modification, the same effect as that in the above-described embodiments can be obtained. In accordance with the first modification, it is effective when a projecting portion cannot be provided to the rear surface 3b (a surface) or when it is difficult to provide the projecting portion.

### Second Modification

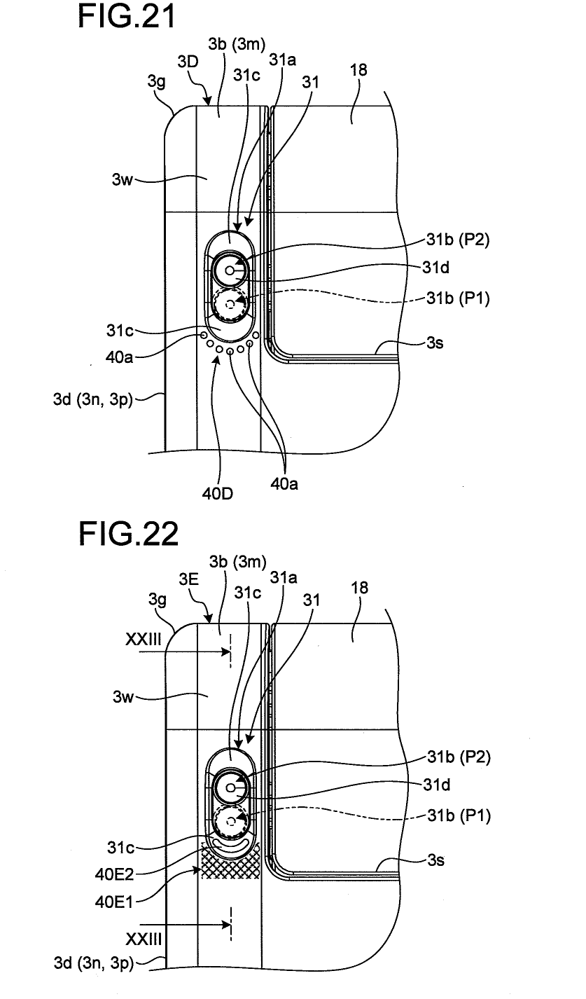

In a second modification, as an example, as illustrated in FIG. 21, a movement suppressing portion 40D replaces the movement suppressing portion 40A in the above-described first and the second embodiments. The second modification is the same as the second embodiment, except that the movement suppressing portion 40D replaces the movement suppressing portion 40A. The movement suppressing portion 40D, as an example, is provided as a plurality of bosses 40a (a projecting portion or a stepped portion). The movement suppressing portion 40D is an example of an irregular portion. In the second modification, the movement suppressing portion 40D as the plurality of bosses 40a is arranged side-by-side in an arc shape (in a semicircle or in a curved line) along the edge of the opening 31a in an arc shape (in a semicircle). Even by the second modification, the same effect as that in the embodiments and the modification described in the foregoing can be obtained. The second modification is also effective when it is difficult to provide a projecting portion on the rear surface 3b (a surface). The movement suppressing portion 40D may be provided in an integrated manner as a part of the wall 3m of a housing 3D, or may be provided by attaching (fitting, mounting, affixing, or pasting) separate members.

### Third Modification

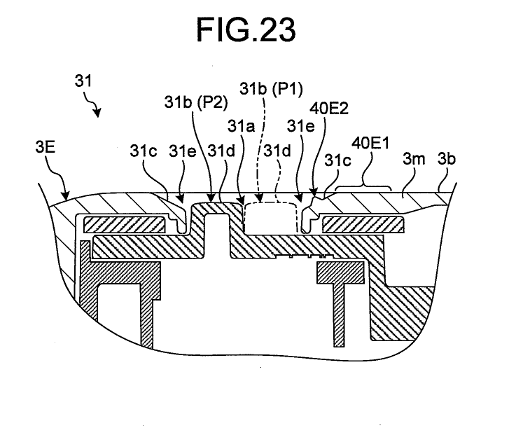

In a third modification, as an example, as illustrated in FIGS. 22 and 23, movement suppressing portions 40E1 and 40E2 replace the movement suppressing portion 40A in the first and the second embodiments described above. The third modification is the same as the second embodiment, except that the movement suppressing portions 40E1 and 40E2 replace the movement suppressing portion 40A. The movement suppressing portion 40E1, as an example, is provided to the rear surface 3b as a rougher (in surface roughness) area than the other areas (a general area) of the rear surface 3b. The movement suppressing portion 40E1, for example, can be formed by irregularities provided to a forming die, or can be provided by performing cutting work, press work, or the like after forming. Furthermore, the movement suppressing portion 40E1 may be provided to the corresponding area by attaching (fitting, mounting, affixing, or pasting) a member of a different surface roughness from the other areas. Examples of the functional effects of the movement suppressing portion 40E1 include the following: the movement of a finger and such is physically obstructed (for example, lowers the moving speed of the finger and such); and the operator is made to distinguish tactilely that it is different from the rear surface 3b by the finger and such contacting the movement suppressing portion 40E1 and to realize that, for example, it is better not to move any further. The movement suppressing portion 40E1 is an example of an irregular portion. The movement suppressing portion 40E1 is also provided in an arc shape (in a semicircle or in a curved line) along the edge of the opening 31a in an arc shape (in a semicircle). Meanwhile, the movement suppressing portion 40E2, as an example, is provided as a projecting portion (a boss, a protruding portion, a wall, or a stepped portion) on the inclined surface 31c. The movement suppressing portion 40E2 is an example of an irregular portion. The movement suppressing portion 40E2 is also provided in an arc shape (in a semicircle or in a curved line) along the edge of the opening 31a in an arc shape (in a semicircle). By the third modification, the same effect as that of the embodiments and the modifications described above can be obtained. In accordance with the third modification, it is effective when it is difficult to provide a projecting portion on the rear surface 3b (a surface). Furthermore, in accordance with the third modification, because two of the movement suppressing portions 40E1 and 40E2 surround (cover) the movable part 31b, the movement of the movable part 31b is further suppressed. In the third modification, the top surface 31d (an apical end or a tip) of the movable part 31b is provided lower than the rear surface 3b. Accordingly, an unintentional operation or an erroneous operation of the movable part 31b is likely to be further suppressed.

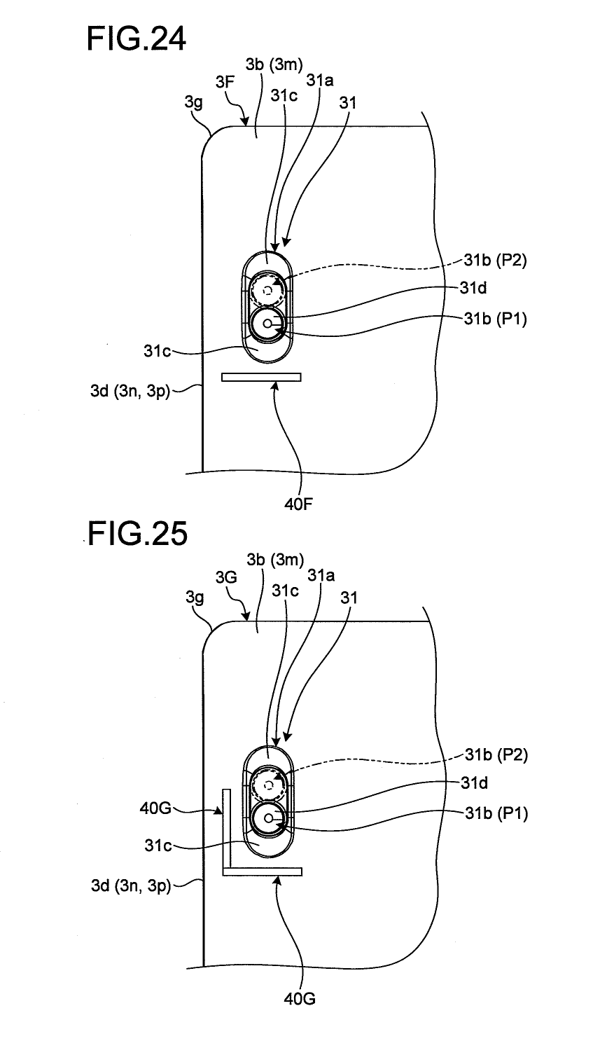

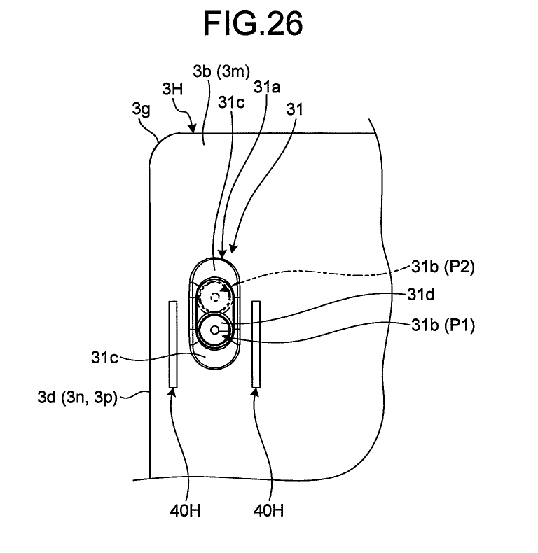

While the exemplary embodiments of the invention are described in the foregoing, the above-described embodiments are illustrative only. The invention is not restricted to the above-described embodiments, and various modifications can be made. For example, the movement suppressing portion can be provided as an area different in surface texture (for example, surface roughness and such) from the other portions (a peripheral area or a general area) of the surface on which the movement suppressing portion is provided. Furthermore, as housings 3F to 3H illustrated in FIGS. 24 to 26, respectively, movement suppressing portions 40F to 40H can be provided in a line (I-shaped) along a direction crossing the longer direction of the opening 31a (FIG. 24), may be provided to surround the movable part 31b in the first position P1 in an L-shape (FIG. 25), or may be provided in an II-shape having two parallel portions extending along the longer direction of the opening 31a (FIG. 26). Furthermore, the technical characteristics of each of the embodiments can be implemented in an appropriate combination. The specifications (construction, type, direction, shape, size, length, width, thickness, height, number, arrangement, position, material, and such) of each of the constituent elements can be implemented with appropriate changes. The configurations according to the embodiments and the modifications described above are further effective for an erroneous operation and an unintentional operation by other than the finger and such when the electronic device is put in a bag and interfered by an object.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television receiver comprising:
a display comprising a display screen;
an electronic component electrically connected to the display;
a housing configured to house the display and the electronic component, the housing comprising an opening on an outer surface of the housing;
a function component partly housed in the housing;
a movable part operable through the opening, the movable part configured to slide along the opening between a first position where a part of a function of the function component is restricted and a second position where the restricted part of the function in the first position is released; and
a recessed portion or a projecting portion away from the first position when viewed from the second position in a direction along the opening or away from the second position when viewed from the first position in a direction along the opening, the recessed portion or the projecting portion in a circumferential area of the opening.

2. The television receiver of claim 1, wherein the recessed portion or the projecting portion comprises a projecting portion surrounding the movable part.

3. The television receiver of claim 2, wherein the projecting portion surrounds the movable part in the first position.

4. The television receiver of claim 2, further comprising a protruding portion on the outer surface, the protruding portion protruding higher than the projecting portion.

5. The television receiver of claim 1, wherein the movable part is lower than the outer surface.

6. The television receiver of claim 1, wherein the opening is at an end of the housing.

7. The television receiver of claim 6, wherein the opening is at a curved portion of the end.

8. The television receiver of claim 1, further comprising:
a second movable part configured to move in the housing, wherein
the movable part is configured to suppress movement of the second movable part when the movable part is in the first position and to not suppress movement of the second movable part when the movable part is in the second position.

9. The television receiver of claim 8, wherein the second movable part is exposed to a surface of the housing different from the outer surface to which the movable part is exposed.

10. An electronic device comprising:
a housing configured to house a display comprising a display screen, the housing comprising an opening;
a movable part exposed through the opening and positioned lower than a part of a circumferential portion of the opening, the movable part configured to slide in the opening along an outer surface of the housing; and
a stepped portion in a part of a circumferential area of the opening.

11. An electronic device comprising:
a housing configured to house a display comprising a display screen, the housing comprising an opening;
a movable part exposed through the opening and positioned lower than a part of a circumferential portion of the opening, the movable part configured to slide along the opening; and
a suppressing portion at one side of the circumferential portion, the suppressing portion configured to suppress movement of the movable part toward an other side of the circumferential portion of the opening.
